(19) United States
(12) Patent Application Publication
(10) Pub. No.: US 2015/0268269 A1
(43) Pub. Date: Sep. 24, 2015

(54) SENSOR WITH COMBINED SENSE ELEMENTS FOR MULTIPLE AXIS SENSING

(71) Applicant: FREESCALE SEMICONDUCTOR, INC., AUSTIN, TX (US)

(72) Inventors: Kemiao Jia, Phoenix, AZ (US); Andrew C. McNeil, Chandler, AZ (US); Michael Naumann, Chandler, AZ (US)

(73) Assignee: FREESCALE SEMICONDUCTOR, INC., Austin, TX (US)

(21) Appl. No.: 14/221,016

(22) Filed: Mar. 20, 2014

(51) Int. Cl. G01P 15/125; B81B 3/00

(52) U.S. Cl. CPC G01P 15/125; B81B 3/0062; B81B 2201/0235

(57) ABSTRACT

A MEMS sensor includes a movable element spaced apart from a surface of a substrate and fixed sense elements attached to the substrate, where all of the fixed sense elements are oriented parallel to one another. The movable element includes movable sense elements adjacent to the fixed sense elements. The movable element is adapted to undergo motion in response to mutually orthogonal forces, each of the forces being substantially parallel to the surface of the substrate. The fixed sense elements detect the motion of the movable element, and differential logic is applied to determine the magnitudes of the mutually orthogonal forces.

### TECHNICAL FIELD OF THE INVENTION

The present invention relates generally to microelectromechanical systems (MEMS) sensors. More specifically, the present invention relates to combined sense elements for sensing in at least two orthogonal axes.

### BACKGROUND OF THE INVENTION

Microelectromechanical systems (MEMS) sensors are widely used to sense a physical condition such as acceleration, angular velocity, pressure, or temperature, and to provide an electrical signal representative of the sensed physical condition. For example, a MEMS accelerometer may sense acceleration or other phenomena. From this information, the movement or orientation of the device in which the accelerometer is installed may be ascertained. Accelerometers are used in inertial guidance systems, in airbag deployment systems in vehicles, in protection systems for a variety of devices, and many other scientific and engineering systems.

Capacitive-sensing MEMS designs are highly desirable for operation in high acceleration environments and in miniaturized devices, due to their relatively low cost. Furthermore, the design requirements for an ever-increasing number of devices are calling for the incorporation of multiple axis sensing capabilities in a compact form factor for added usability and functionality. However, there is an ongoing need for an improved MEMS sensor device, such as a MEMS capacitive accelerometer, that is capable of multiple axis sensing and that additionally achieves efficient die area size without increasing manufacturing cost or sacrificing part performance.

### BRIEF DESCRIPTION OF THE DRAWINGS

A more complete understanding of the present invention may be derived by referring to the detailed description and claims when considered in connection with the Figures, wherein like reference numbers refer to similar items throughout the Figures, the Figures are not necessarily drawn to scale, and:

FIG. 1 shows a top view of a microelectromechanical systems (MEMS) sensor in accordance with an embodiment;

FIG. 2 shows a side sectional view of the MEMS sensor along section lines 2-2 of FIG. 1;

FIG. 3 shows a simplified side sectional view of the MEMS sensor along section lines 3-3 of FIG. 1;

FIG. 4 shows a block diagram of a MEMS sensor package that incorporates the MEMS sensor of FIG. 1;

FIG. 5 shows a simplified top schematic view of the MEMS sensor being subjected to an acceleration stimulus;

FIG. 6 shows a simplified top schematic view of the MEMS sensor being subjected to another acceleration stimulus;

FIG. 7 shows a simplified top schematic view of a MEMS sensor being subjected to another acceleration stimulus in accordance with another embodiment; and

FIG. 8 shows a flowchart of a multiple axis sensing process in accordance with another embodiment.

### DETAILED DESCRIPTION

Embodiments of the invention entail a compact microelectromechanical systems (MEMS) sensor, for example, an accelerometer, that is capable of sensing a force (e.g., a net force such as acceleration) along two or more axes. In particular, multiple axis sensing can be adapted to detect acceleration in two orthogonal axes that are parallel to a planar surface of the sensor. In some configurations, the MEMS sensor may be further adapted to detect acceleration along an axis that is perpendicular to the planar surface of the sensor. A compact design with high sensitivity can be achieved by combining sense elements to sense the forces along the two orthogonal axes that are parallel to a planar surface of the sensor.

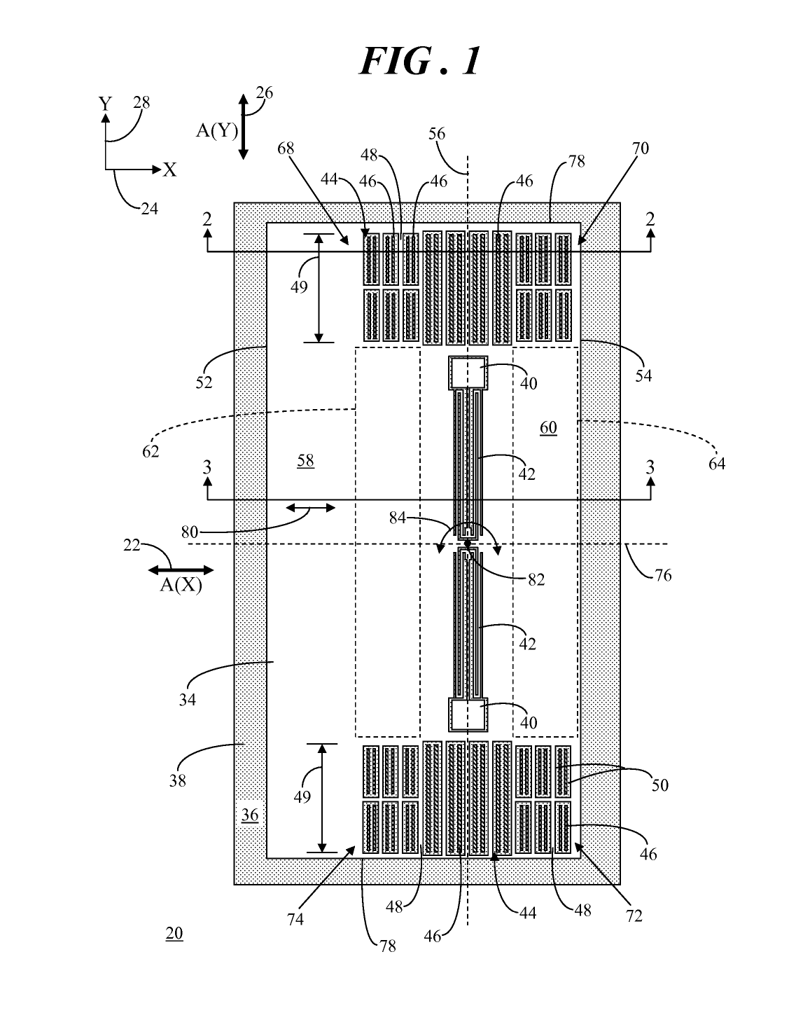

Referring now to FIGS. 1-3, FIG. 1 shows a top view of a microelectromechanical systems (MEMS) sensor 20 in accordance with an embodiment. FIG. 2 shows a side sectional view of MEMS sensor 20 along section lines 2-2 of FIG. 1, and FIG. 3 shows a simplified side sectional view of MEMS sensor 20 along section lines 3-3 of FIG. 1. Sensor 20 may be, for example, an accelerometer or other MEMS sensing device. For purposes of the following discussion, MEMS sensor 20 is referred to hereinafter as accelerometer 20. However, sensor 20 need not be an accelerometer, but may be any other MEMS sensor (e.g., gyroscope) adapted to sense a force along at least two mutually orthogonal axes, both of which are parallel to a surface of the MEMS sensor.

In an embodiment, accelerometer 20 is a multiple axis sensor adapted to detect a net force, i.e., acceleration along each of three orthogonal axes. As illustrated in FIG. 1, accelerometer 20 is capable of detecting an X-axis acceleration stimulus 22 (labeled A(X)), along an X-axis 24 in a three-dimensional coordinate system. Additionally, accelerometer 20 is capable of detecting a Y-axis acceleration stimulus 26 (labeled A(Y)), along a Y-axis 28 in the three-dimensional coordinate system. As further illustrated in FIG. 3, accelerometer 20 is also capable of detecting a Z-axis acceleration stimulus 30 (labeled A(Z)), that along a Z-axis 32 in the three-dimensional coordinate system. Accelerometer 20 achieves a compact configuration while concurrently providing significant capacitive output corresponding to acceleration stimuli 22, 26, and 30.

FIGS. 1-3 are illustrated using various shading and/or hatching to distinguish the different elements produced within the structural layers of MEMS accelerometer 20, as will be discussed below. These different elements within the structural layers may be produced utilizing current and upcoming surface micromachining techniques of depositing, patterning, etching, and so forth. Accordingly, although different shading and/or hatching is utilized in the illustrations, the different elements within the structural layers are typically formed out of the same material, such as polysilicon, single crystal silicon, and the like.

The elements of accelerometer 20 (discussed below) may be described variously as being “attached to,” “attached with,” “coupled to,” “fixed to,” or “interconnected with,” other elements of accelerometer 20. It should be understood that these terms refer to the direct or indirect physical connections of particular elements of accelerometer 20 that occur during their formation through patterning and etching processes of MEMS fabrication. However, the terms “direct” or “directly” preceding any of the above terms refers expressly to the physical connection of particular elements of accelerometer 20 with no additional intervening elements.

Accelerometer 20 includes a movable element 34 spaced apart from a surface 36 of a substrate 38. Suspension anchors 40 are formed on substrate 38 and compliant members 42 interconnect movable element 34 with suspension anchors 40 so that movable element 34 is suspended above substrate 38. Compliant members 42 enable movement of movable element 34 relative to surface 36 of substrate 38.

A plurality of openings 44 extend through movable element 34. Pairs of fixed sense elements 46 reside in openings 44 and are attached to substrate 38 such that they are substantially immovable relative to surface 36 of substrate 38. As particularly illustrated in FIG. 1, each of fixed sense elements 46 are oriented substantially parallel to one another. Additionally, sense elements 46 of each pair are electrically, thus mechanically, isolated from one another in order to achieve differential sensing capability.

Fixed sense elements 46 are arranged adjacent to movable sense elements. More particularly, portions of movable element 34 are positioned between, and therefore are adjacent to, fixed sense elements 46. These portions of movable element 34 are referred to herein as movable sense elements 48 since they are capable of movement in conjunction with the remainder of movable element 34 relative to surface 36 of substrate 38. Fixed and movable sense elements 48 are arranged substantially parallel to surface 36 of substrate 38 and are oriented such that their length 49 is oriented perpendicular to X-axis 24, and sense gaps 50 are formed between each side of movable sense elements 48 and the adjacent fixed sense elements 46.

Only a few fixed sense elements 46 and movable sense elements 48 are shown for clarity of illustration. Alternative embodiments may include fewer or more than the pairs of sense elements 46, 48 illustrated herein. Regardless of the quantity of sense elements 46, 48, all fixed sense elements 46 in the illustrated embodiment and in alternative embodiments are oriented substantially parallel to one another and are consequently oriented substantially parallel to movable sense elements 48.

Movable element 34 is a generally planar structure having opposing ends 52 and 54. A reference axis 56, oriented substantially parallel to Y-axis 28, is located between ends 52, 54 to form a section 58 of movable element 34 between reference axis 56 and end 52, and to form another section 60 of movable element 34 between reference axis 56 and end 54. Section 58 exhibits a relatively greater mass than section 60. This is typically accomplished by offsetting reference axis 56 such that section 58 is longer than section 60. However, in other configurations, the greater mass of section 58 relative to section 60 may be accomplished, where sections 58 and 60 are of relatively identical lengths, by adding mass to section 58, removing mass from section 60, or some combination thereof.

In the illustrated embodiment, reference axis 56 is a rotational axis. That is, movable element 34 is further adapted to rotate or pivot about reference axis 56 in response to Z-axis acceleration stimulus 30. As such, reference axis 56 is referred to hereinafter as rotational axis 56. A sense element 62 is disposed on surface 36 of substrate 38 opposing section 58, and another sense element 64 is disposed on surface 36 of substrate 38 opposing section 60. Sense elements 62, 64 are visible in the side view illustration of FIG. 3. However, sense elements 62, 64 are shown in dashed line form in FIG. 1 since they underlie movable element 34. Only two sense elements 62, 64 are shown for simplicity of illustration. In alternative embodiments, accelerometer 20 may include a different quantity and/or different configuration of sense/electrode elements formed on substrate 38 opposing movable element 34.

Fixed and movable sense elements 46, 48 are delineated into four groups of adjacent pairs of sense elements 46, 48. The groups of adjacent pairs of sense elements 46, 48 are referred to herein as a first group 68, a second group 70, a third group 72, and a fourth group 74 of adjacent pairs of sense elements 46, 48. In this example, a reference axis 76 coincides with a centerline of accelerometer 20 and is parallel to X-axis 24. Another reference axis coincides with rotational axis 56 and is parallel to Y-axis 28. For simplicity, this second reference axis is variously referred to herein as reference axis 56 or rotational axis 56. Thus, both of reference axis 76 and rotational axis 56 are substantially parallel to surface 36 of substrate 38, and rotational axis 56 is orthogonal to reference line 76. The terms “first,” “second,” “third,” and “fourth” utilized herein are not necessarily intended to indicate temporal or other prioritization of such elements. Rather, the terms “first,” “second,” “third,” and “fourth” are used to delineate separate features, such as groupings of sense elements 46, 48 for clarity of illustration.

In an embodiment, first and fourth groups 68, 74 are symmetrically positioned opposing one another on opposite sides of reference axis 76 and second and third groups 70, 72 are symmetrically positioned opposing one another on opposite sides of reference axis 76. Additionally, first and second groups 68, 70 are symmetrically positioned opposing one another on opposite sides of rotational axis 56 (i.e., the second reference line), and third and fourth groups are symmetrically positioned opposing one another on opposite sides of rotational axis 56. Thus, sense elements 46, 48, are subdivided into four distinct groups 68, 70, 72, 74 delineated by reference axis 76 and rotational axis 56.

It should be observed in FIG. 1 that groups 68, 70, 72, and 74 of adjacent pairs of sense elements 46, 48 are displaced away from reference axis 76. That is, sense elements 46, 48 are placed toward an outer edge 78 of movable element 34 to achieve higher sensitivity to Y-axis acceleration 26 (discussed below). Additionally, groups 68, 70, 72, and 74 of adjacent pairs of sense elements 46, 48 are spatially separated from sense elements 62, 64 to largely prevent interference between sense elements 62, 64, and sense elements 46, 48.

In an embodiment, compliant members 42 enable movement of movable element 34 in response to X-axis acceleration 22. In the exemplary embodiment, movable element 34 is adapted to undergo translational motion that is substantially parallel to surface 36 of substrate 38 in response to X-axis acceleration 22. In connection with the illustrated embodiment, the translational motion of movable element 34 is leftward and rightward along X-axis 24 in the page upon which FIG. 1 is presented. The translational motion of movable element 34 in response to X-axis acceleration 22 is represented by a bi-directional straight arrow 80 in FIG. 1, and is referred to herein as translational motion 80.

Additionally, compliant members 42 enable movement of movable element 34 in response to Y-axis acceleration 26. In the exemplary embodiment, movable element 34 is adapted to undergo pivotal motion about a pivot axis that is substantially perpendicular to surface 36 of substrate 38 in response to Y-axis acceleration 26. In connection with the illustrated embodiment, the pivotal motion of movable element 34 is about a pivot axis, which represented by a dark circle 82 in FIG. 1 and which is referred to herein as pivot axis 82. Pivot axis 82 extends perpendicular to the page upon which FIG. 1 is presented, and is thus aligned with Z-axis 30 (see FIG. 3). The pivotal motion of movable element 34 about pivot axis 82 in response to Y-axis acceleration 26 is represented by a bi-directional curved arrow 84 in FIG. 1, and is referred to herein as pivotal motion 84.

In some embodiments, such as in accelerometer 20, compliant members 42 additionally enable movement of movable element 34 in response to Z-axis acceleration 30. In the exemplary embodiment, movable element 34 is further adapted to undergo pivotal motion about rotational axis 56 in response to Z-axis acceleration 30, where rotational axis 56 is substantially parallel to surface 36 of substrate 38 and is aligned with Y-axis 28. The pivotal motion of movable element 34 about rotational axis 56 in response to Z-axis acceleration 30 is represented by a bi-directional curved arrow 86 in FIG. 3, and is referred to herein as pivotal motion 86.

To summarize, movable element 34 is adapted to undergo translational motion 80 that is parallel to surface 36 of substrate 38 along X-axis 24 in response to X-axis acceleration 22. Movable element 34 is adapted to undergo pivotal motion 84 about pivot axis 82 that is perpendicular to surface 36 of substrate 38 in response to Y-axis acceleration 26. And, movable element 34 further adapted to undergo pivotal motion 86 about rotational axis 56 that is oriented parallel to surface 36 of substrate 38 in response to Z-axis acceleration 30. In alternative embodiments, however, a movable element may be a dual axis sensor adapted to undergo motion in response to X-axis acceleration 22 and Y-axis acceleration 26, without being adapted to undergo motion in response to Z-axis acceleration 30

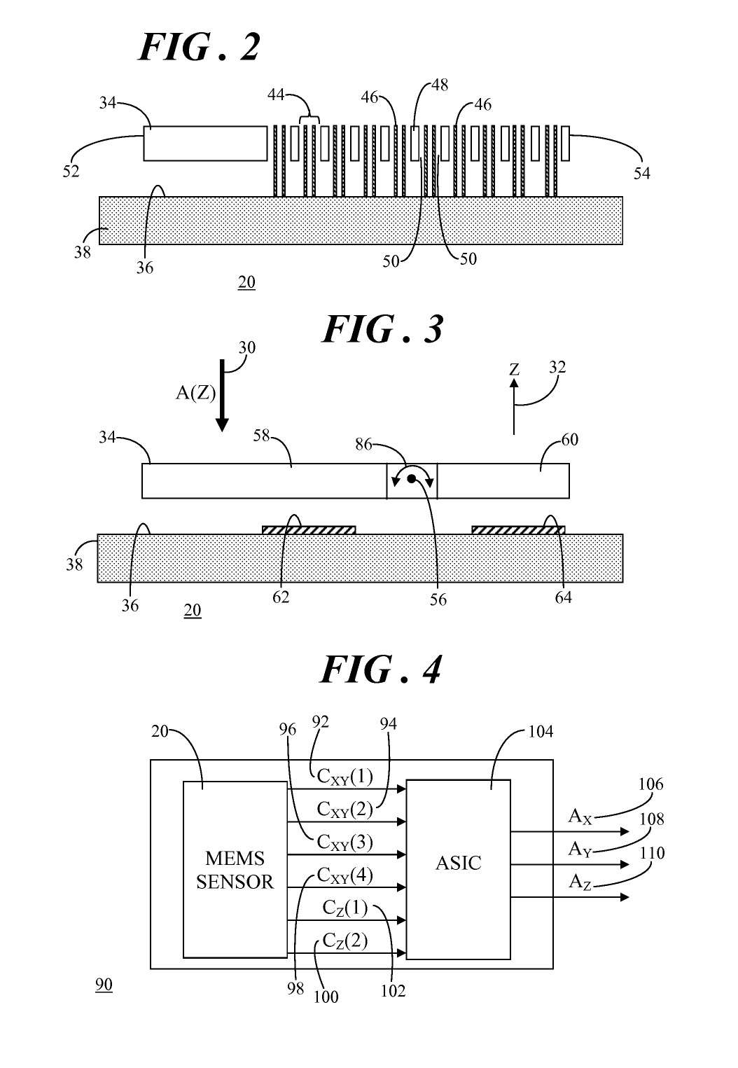

FIG. 4 shows a block diagram of a MEMS sensor package 90 that incorporates MEMS accelerometer 20. Accelerometer 20 may be a capacitive-sensing accelerometer. In general, capacitive-sensing accelerometers produce an electrical capacitance that changes in response to a change in acceleration so as to vary the output of an energized circuit.

In accordance with an embodiment, each of first, second, third, and fourth groups 68, 70, 72, 74 (FIG. 1) of sense elements 46, 48 (FIG. 1) sense an electrical capacitance in response to both of X-axis acceleration 22 and Y-axis acceleration 26. The electrical capacitance sensed by first group 68 of sense elements 46, 48 is referred to herein as a first capacitance 92, and is labeled C_{XY}(1). The electrical capacitance sensed by second group 70 of sense elements 46, 48 is referred to herein as a second capacitance 94, and is labeled C_{XY}(2). The electrical capacitance sensed by third group 72 of sense elements 46, 48 is referred to herein as a third capacitance 96, and is labeled C_{XY}(3). And, the electrical capacitance sensed by fourth group 74 of sense elements 46, 48 is referred to herein as a fourth capacitance 98, and is labeled C_{XY}(4). Again, the terms “first,” “second,” “third,” and “fourth” utilized herein do not refer to a temporal or other prioritization of features. Rather, the terms “first,” “second,” “third,” and “fourth” in conjunction with capacitances 92, 94, 96, 98 are used to correspond with the groups 68, 70, 72, 74 of sense elements 46, 48 for clarity of description.

Since accelerometer 20 is additionally adapted to sense Z-axis acceleration 30 (FIG. 3), sense elements 62, 64 (FIG. 3) sense a change in electrical capacitance with respect to Z-axis acceleration 30. The change in electrical capacitance between sense element 62 and movable element 34 is referred to herein as a first Z-axis capacitance 100, and is labeled C_{Z}(l). Similarly, the change in electrical capacitance between sense element 64 and movable element 34 is referred to herein as a second Z-axis capacitance 102, and is labeled C_{Z}(2).

Sensor package 90 may include an application specific integrated circuit (ASIC) 104. ASIC 104 is configured to receive capacitances 92, 94, 96, 98, 100, 102 sensed at accelerometer 20 and suitably process them to produce a value indicative of a magnitude 106 of X-axis acceleration 22, labeled Aₓ, a value indicative of a magnitude 108 of Y-axis acceleration 26, labeled A_{Y}, and a value indicative of a magnitude 110 of Z-axis acceleration 30, labeled A_{z}. In general, ASIC 104 receives capacitances 92, 94, 96, 98 and applies differential logic to them to determine magnitude 106 of X-axis acceleration 22 and magnitude 108 of Y-axis acceleration 26. Additionally, ASIC 104 receives capacitances 102 and 104 and applies differential logic to them to determine magnitude 110 of Z-axis acceleration 30. ASIC 104 is shown beside MEMS sensor 20 for simplicity of illustration. However, ASIC 104 need not be integrated with MEMS sensor 20 in a side-by-side configuration. In alternative embodiments, ASIC and MEMS sensor 20 may be in a stacked die configuration, a monolithic configuration, or any other known or upcoming packaging configuration.

FIGS. 5-7 (discussed below) are presented to demonstrate the application of differential logic to determine magnitude 106 of X-axis acceleration 22 and magnitude 108 of Y-axis acceleration 26 from capacitances 92, 94, 96, 98 in accordance with embodiments of the invention.

FIG. 5 shows a simplified top schematic view of MEMS sensor 20 being subjected to axis acceleration stimulus 22, which causes movable element 34 to undergo translational motion 80 along X-axis 24. Translational motion 80 is opposite to the direction of X-axis acceleration 22. Accordingly, the arrow representing X-axis acceleration 22 is pointing leftward and the arrow representing translational motion 80 is pointing rightward in the illustrated embodiment.

In FIG. 5, groups 68, 70, 72, 74 are delineated by dotted line boxes. For simplicity, all of sense elements 46, 48 within first group 68 are represented by a single fixed sense element 46 and a single movable sense element 48. Likewise, all of sense elements 46, 48 within second group 70 are represented by a single fixed sense element 46 and a single movable sense element 48. All of sense elements 46, 48 within third group 72 are represented by a single fixed sense element 46 and a single movable sense element 48. And, all of sense elements 46, 48 within fourth group 74 are represented by a single fixed sense element 46 and a single movable sense element 48. As discussed previously, each of groups 68, 70, 72, and 74 can include any number of sense elements 46, 48 dictated by the design and a target sensitivity for MEMS accelerometer 20. Thus, fixed sense elements 46 in each of groups 68, 70, 72, and 74 may be suitably linked by conductive traces, or polyrunners, as known to those skilled in the art, to sum the individual capacitances within each group 68, 70, 72, and 74.

As shown in this illustration, when movable element 34 is subjected to X-axis acceleration 22, it undergoes translational motion 80 so that the distance between each of fixed sense elements 46 and their adjacent movable sense elements 48 changes. It should be understood that translational motion 80 of movable element 34 shown in FIG. 5 is exaggerated for illustrative purposes.

Due to the deflection of movable element 34, the capacitance changes between fixed and movable sense elements 46, 48. This change in capacitance is registered by ASIC 104 (FIG. 4). As shown, the change in capacitance between sense elements 46, 48 of first group 68 is first capacitance 92. The change in capacitance between sense elements 46, 48 of second group 70 is second capacitance 94. The change in capacitance between sense elements 46, 48 of third group 72 is third capacitance 96. And, the change in capacitance between sense elements 46, 48 of fourth group 74 is fourth capacitance 98.

In order to evaluate and determine magnitude 106 of X-axis acceleration 22, ASIC 104 applies the following logic for differential sensing:

A(X)≈[C_{XY}(2)+C_{XY}(3)]−[C_{XY}(1)+C_{XY}(4)] (1)

Thus, magnitude 106 of X-axis acceleration 22 is proportional to a summation of capacitances 94, 96 of second and third groups 70, 72 of sense elements 46, 48 subtracted by a summation of capacitances 92, 98 of first and fourth groups 68, 74 of sense elements 46, 48.

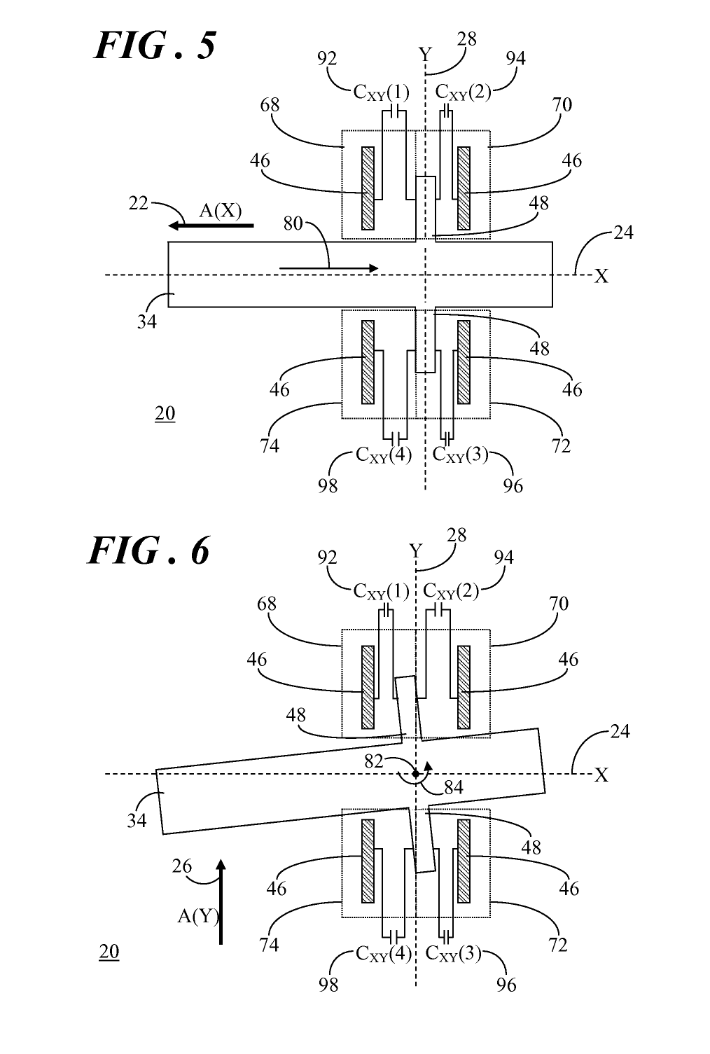

FIG. 6 shows a simplified top schematic view of MEMS sensor 20 being subjected to Y-axis acceleration stimulus 26, which causes movable element 34 to undergo pivotal motion 84 of movable element 34 about pivot axis 82. Pivotal motion 84 of movable element 34 opposes the direction of Y-axis acceleration stimulus 26. Accordingly, the arrow representing Y-axis acceleration stimulus 26 is pointing upwardly and the curved arrow representing pivotal motion 84 is directed counterclockwise. Again, groups 68, 70, 72, 74 are delineated by dotted line boxes and the total quantity of sense elements 46, 48 in each of groups 68, 70, 72, 74 is represented by a single fixed sense element 46 and a single movable sense element 48 for simplicity of illustration.

As shown in this illustration, when movable element 34 is subjected to Y-axis acceleration 26, it undergoes pivotal motion 84 about pivot axis 82, due at least in part to the greater mass of section 58 relative to section 60 of movable element 34. The differing mass of section 58 relative to section 60 causes an imbalance so that movable element 34 pivots about pivot axis 82. It should be understood that pivotal motion 84 of movable element 34 shown in FIG. 6 is exaggerated for illustrative purposes.

Pivotal motion 84 also changes the distance between each of fixed sense elements 46 and their adjacent movable sense elements 48 changes. Consequently, capacitances 92, 94, 96, 98 change between fixed and movable sense elements 46, 48 of respective groups 68, 70, 72, 74 and are registered by ASIC 104 (FIG. 4). In order to evaluate and determine magnitude 108 of Y-axis acceleration 26, ASIC 104 applies the following logic for differential sensing:

A(Y)≈[C_{XY}(1)+C_{XY}(3)]−[C_{XY}(2)+C_{XY}(4)] (2)

Thus, magnitude 108 of Y-axis acceleration 26 is proportional to a summation of capacitances 92, 96 of first and third groups 68, 72 of sense elements 46, 48 subtracted by a summation of capacitances 94, 98 of second and fourth groups 70, 74 of sense elements 46, 48.

Although translational motion 80 is shown in FIG. 5 and pivotal motion 84 is shown in FIG. 6, is should be understood that the motion of movable element at a given instant may be a combination of translational motion 80 and pivotal motion 84. Capacitances 92, 94, 96, and 98 are thus used to determine both X-axis acceleration 22 and Y-axis acceleration 26 at that instant. For example, when there is X-axis acceleration 22 and no Y-axis acceleration 26, magnitude 106 determined via Equation (1) scales with X-axis acceleration 22 and magnitude 108 determined via Equation (2) is zero. When there is Y-axis acceleration 26 and no X-axis acceleration 22, magnitude 108 determined via Equation (2) scales with Y-axis acceleration 26, and magnitude 106 determined via Equation (1) is zero. When there is both X-axis acceleration 22 and Y-axis acceleration 26, each of magnitude 106 determined via Equation (1) and magnitude 108 determined via Equation (2) scale with X-axis acceleration 22 and Y-axis acceleration 26, respectively.

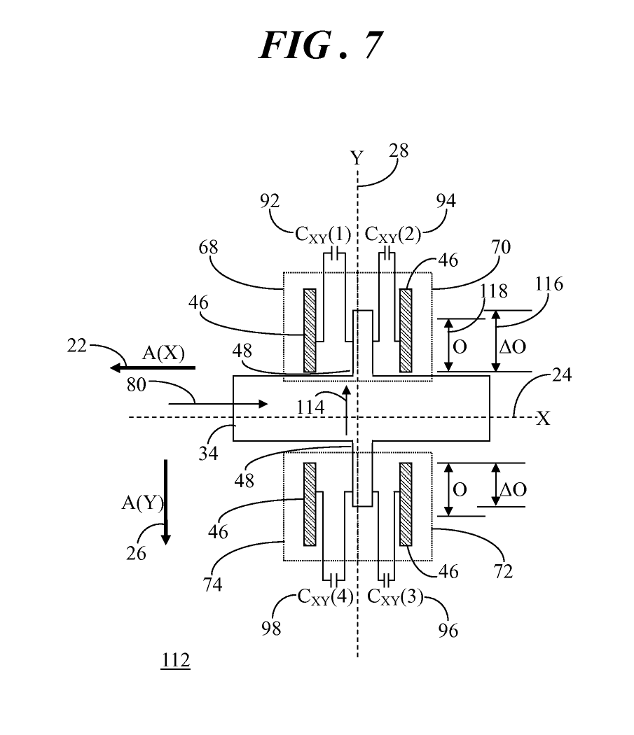

FIG. 7 shows a simplified top schematic view of a MEMS sensor 112 being subjected to an acceleration stimulus in accordance with another embodiment. In particular, MEMS sensor 112 is being subjected to Y-axis acceleration stimulus 26. For illustrative purposes, MEMS sensor 112 is concurrently being subjected to X-axis acceleration stimulus 22. In this example, however, MEMS sensor 112 includes compliant members (not shown) which cause movable element 34 to undergo translational motion 114 along Y-axis 28, as well as translational motion 80 along X-axis 24. Again, groups 68, 70, 72, 74 are delineated by dotted line boxes and the total quantity of sense elements 46, 48 in each of groups 68, 70, 72, 74 is represented by a single fixed sense element 46 and a single movable sense element 48 for simplicity of illustration.

As shown in this illustration, when movable element 34 is subjected to X-axis acceleration 22, it undergoes translational motion 80, which can be determined in accordance with Equation (1). As further illustrated, when movable element 34 is subjected to Y-axis acceleration 26, it undergoes translational motion 114, rather than pivotal motion 84 illustrated in FIG. 6. Again, capacitances 92, 94, 96, 98 change between fixed and movable sense elements 46, 48 of respective groups 68, 70, 72, 74 and are registered by ASIC 104 (FIG. 4). In order to evaluate and determine magnitude 108 of Y-axis acceleration 26, ASIC 104 applies the following logic for differential sensing:

A(Y)≈[C_{XY}(1)+C_{XY}(2)]−[C_{XY}(3)+C_{XY}(4)] (3)

Thus, magnitude 108 of Y-axis acceleration 26 in this example is proportional to a summation of capacitances 92, 94 of first and second groups 68, 70 of sense elements 46, 48 subtracted by a summation of capacitances 96, 98 of third and fourth groups 72, 74 of sense elements 46, 48. This change in capacitances 92, 94, 96, 98 relies on a change of overlap area 116 of sense elements 46, 48 relative to a nominal overlap area 118.

Regardless of the particular structural configuration for detecting Y-axis acceleration 26 as demonstrated in FIGS. 6 and 7, per convention, when movable element 34 is subjected to Z-axis acceleration 30, it undergoes pivotal motion 86 about rotational axis 56, due at least in part to the greater mass of section 58 relative to section 60 of movable element 34. Referring briefly back to FIG. 3, the differing mass of section 58 relative to section 60 causes an imbalance so that movable element 34 pivots about rotational axis 56. Pivotal motion 86 changes the distance between movable element 34 and the underlying sense elements 62. Consequently, capacitances 100 and 102 (FIG. 4) change and are registered by ASIC 104 (FIG. 4). As known to those skilled in the art, in order to evaluate and determine magnitude 110 of Z-axis acceleration 30, ASIC 104 may apply the following logic for differential sensing:

A(Z)≈C_{Z}(1)−C_{Z}(2) (4)

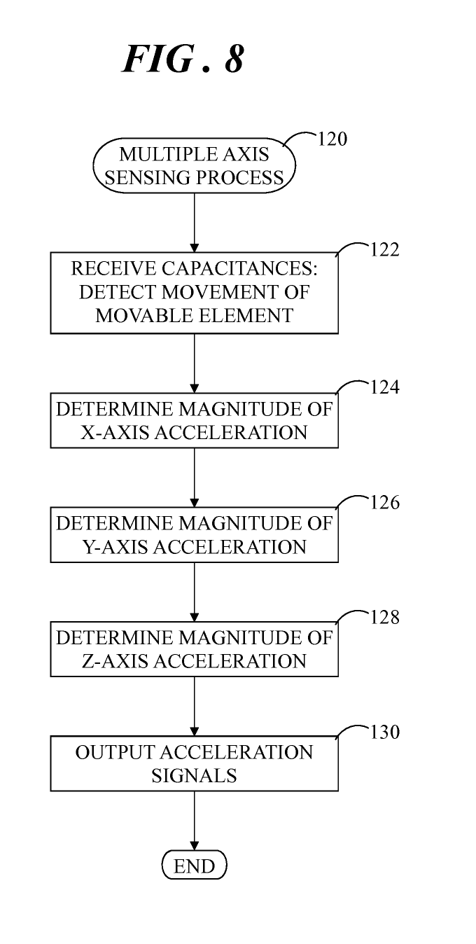

FIG. 8 shows a flowchart of a multiple axis sensing process 120 in accordance with another embodiment. Generally, capacitances 92, 94, 96, 98, 100, 102 are received at ASIC 104 (122). Movement of movable element 34 is detected as a change in one or more values of capacitances 92, 94, 96, 98, 100, 102 relative to nominal. ASIC 104 determines magnitude 106 of X-axis acceleration 22 by implementing Equation (1) (124). ASIC 104 determines magnitude 108 of Y-axis acceleration 22 by implementing Equations (2) or (3) (126). ASIC 104 determines magnitude 110 of Z-axis acceleration 30 by implementing Equation (4) (128). Subsequently, ASIC 104 outputs the acceleration signals, i.e., magnitudes 106, 108, and 110 to end a single iteration of multiple axis sensing process 120. Of course, process 120 can be continuously repeated to continuously provide magnitudes 106, 108, and 110 of X-axis, Y-axis, and Z-axis accelerations 106, 108, and 110, respectively.

By now it should be appreciated that embodiments of the invention entail a compact MEMS sensor, for example, an accelerometer, that is capable of sensing a force, e.g., a net force such as acceleration, along two or more axes. Further embodiments entail a method of multiple axis sensing using the MEMS sensor. The MEMS sensor is adapted to detect forces in two orthogonal axes that are parallel to a planar surface of the sensor. In particular, all fixed sense elements are utilized to detect, for example, acceleration along both of the two orthogonal axes (e.g., X-axis and Y-axis) and differential logic is implemented for evaluating the acceleration. In some configurations, the MEMS sensor may be further adapted to detect acceleration along an axis that is perpendicular to the planar surface of the sensor (e.g., the Z-axis). A compact design with high sensitivity can be achieved by combining sense elements to sense the forces along the two orthogonal axes that are parallel to a planar surface of the sensor.

One embodiment of the invention provides a MEMS sensor that includes a movable element spaced apart from a surface of a substrate, the movable element including first sense elements. The movable element is adapted to undergo first motion in response to a first force and second motion in response to a second force, wherein the first and second forces are mutually orthogonal, and the first and second forces are substantially parallel to the surface of the substrate. The MEMS sensor further includes second sense elements attached to the substrate, the second sense elements being immovable relative to the surface of the substrate, wherein the second sense elements are oriented substantially parallel to one another and are arranged adjacent to the first sense elements, and wherein the second sense elements are immovable relative to the surface of the substrate. The second sense elements are adapted to detect the first and second motion of the movable element.

Another embodiment of the invention provides a method of multiple axis sensing using the MEMS sensor, wherein the method includes steps for detecting first and second motion of the movable element relative to the second sense elements, determining a first magnitude of the first force in response to the first motion, and determining a second magnitude of the second force in response to the second motion.

While the principles of the inventive subject matter have been described above in connection with specific embodiments, it is to be clearly understood that the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims. Further, the phraseology or terminology employed herein is for the purpose of description and not of limitation.

The foregoing description of specific embodiments reveals the general nature of the inventive subject matter sufficiently so that others can, by applying current knowledge, readily modify and/or adapt it for various applications without departing from the general concept. Therefore, such adaptations and modifications are within the meaning and range of equivalents of the disclosed embodiments. The inventive subject matter embraces all such alternatives, modifications, equivalents, and variations as fall within the spirit and broad scope of the appended claims.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

What is claimed is:

1. A micro electromechanical systems (MEMS) sensor comprising:
a movable element spaced apart from a surface of a substrate, said movable element including first sense elements, said movable element being adapted to undergo first motion in response to a first force, and said movable element being further adapted to undergo second motion in response to a second force, said first and second forces being mutually orthogonal, and said first and second forces being substantially parallel to said surface of said substrate; and
second sense elements attached to said substrate, said second sense elements being immovable relative to said surface of said substrate, wherein said second sense elements are oriented substantially parallel to one another and are arranged adjacent to said first sense elements, and wherein said second sense elements are adapted to detect said first and second motion of said movable element.

2. The MEMS sensor of claim 1 wherein:
said first motion of said movable element in response to said first force is translational motion substantially parallel to said surface of said substrate; and
said second motion of said movable element in response to said second force is pivotal motion about a pivot axis that is substantially perpendicular to said surface of said substrate

3. The MEMS sensor of claim 1 wherein said movable element further includes first and second ends, and a reference axis located between said first and second ends to form a first section between said reference axis and said first end and a second section between said reference axis and said second end, said first section exhibiting a greater mass than said second section.

4. The MEMS sensor of claim 3 wherein said second motion of said movable element in response to said second force is pivotal motion about a pivot axis that is substantially perpendicular to said surface of said substrate, said reference axis is oriented substantially parallel to said surface of said substrate, and said pivot axis intersects said reference axis.

5. The MEMS sensor of claim 3 wherein said reference axis is a rotational axis, and said MEMS sensor further comprises:
a third sense element opposing said first section of said movable element; and
a fourth sense element opposing said second section of said movable element, wherein said movable element is further adapted to undergo third motion about said rotational axis, and said third and fourth sense elements are adapted to detect said third motion of said movable element in response to a third force, said third force being substantially perpendicular to said surface of said substrate.

6. The MEMS sensor of claim 1 wherein said first motion of said movable element in response to said first force is translational motion substantially parallel to said surface of said substrate, and said first and second sense elements are lengthwise oriented substantially perpendicular to said first direction of said movement of said movable element.

7. The MEMS sensor of claim 1 wherein all of said first and second sense elements are concurrently utilized to sense both of said first and second forces.

8. The MEMS sensor of claim 1 wherein said first and second sense elements comprise:
a first group of adjacent pairs of said first and second sense elements;
a second group of adjacent pairs of said first and second sense elements;
a third group of adjacent pairs of said first and second sense elements; and
a fourth group of adjacent pairs of said first and second sense elements, wherein said first and fourth groups are positioned opposing one another on opposite sides of a first reference axis, said second and third groups are positioned opposing one another on opposite sides of said first reference axis, said first and second groups are positioned opposing one another on opposite sides of a second reference axis, said third and fourth groups are positioned opposing one another on opposite sides of said second reference axis, said first and second reference axes being substantially parallel to said surface of said substrate, and said second reference axis being orthogonal to said first reference axis.

9. The MEMS sensor of claim 8 wherein said second motion of said movable element in response to said second force is pivotal motion about a pivot axis substantially perpendicular to said surface of said substrate, said pivot axis being located at an intersection of said first and second reference axes.

10. The MEMS sensor of claim 8 wherein a magnitude of said first force is proportional to a first summation of capacitances between said first and second sense elements of said second and third groups subtracted by a second summation of capacitances between said first and second sense elements of said first and fourth groups.

11. The MEMS sensor of claim 8 wherein a magnitude of said second force is proportional to a first summation of capacitances between said first and second sense elements of said first and third groups subtracted by a second summation of capacitances between said first and second sense elements of said second and fourth groups.

12. The MEMS sensor of claim 1 wherein said first force comprises a first acceleration stimulus and said second force comprises a second acceleration stimulus.

13. A microelectromechanical systems (MEMS) sensor comprising:
a movable element spaced apart from a surface of a substrate, said movable element including:
first sense elements;
first and second ends, wherein a reference axis is located between said first and second ends;
a first section formed between said reference axis and said first end; and
a second section formed between said reference axis and said second end, said first section exhibiting a greater mass than said second section, wherein:
said movable element is adapted to undergo translational motion substantially parallel to said surface of said substrate in response to a first force; and
said movable element is further adapted to undergo pivotal motion about a pivot axis in response to a second force, said pivot axis being substantially perpendicular to said surface of said substrate, said first and second forces being mutually orthogonal, and said first and second forces being substantially parallel to said surface of said substrate; and
second sense elements attached to said substrate, said second sense elements being immovable relative to said surface of said substrate, wherein said second sense elements are oriented substantially parallel to one another and are arranged adjacent to said first sense elements, and wherein said second sense elements are adapted to detect said translational motion and pivotal motion of said movable element.

14. The MEMS sensor of claim 13 wherein said reference axis is a rotational axis oriented substantially parallel to said surface of said substrate, and said MEMS sensor further comprises:
a third sense element opposing said first section of said movable element; and
a fourth sense element opposing said second section of said movable element, wherein said movable element is further adapted to undergo second pivotal motion about said rotational axis, and said third and fourth sense elements are adapted to detect said second pivotal motion of said movable element in response to a third force, said third force being substantially perpendicular to said surface of said substrate.

15. The MEMS sensor of claim 13 wherein said first and second sense elements comprise:
a first group of adjacent pairs of said first and second sense elements;
a second group of adjacent pairs of said first and second sense elements;
a third group of adjacent pairs of said first and second sense elements; and
a fourth group of adjacent pairs of said first and second sense elements, wherein said first and fourth groups are positioned opposing one another on opposite sides of a first reference axis, said second and third groups are positioned opposing one another on opposite sides of said first reference axis, said first and second groups are positioned opposing one another on opposite sides of a second reference axis, said third and fourth groups are positioned opposing one another on opposite sides of said second reference axis, said first and second reference axes being substantially parallel to said surface of said substrate, and said second reference axis being orthogonal to said first reference axis.

16. The MEMS sensor of claim 15 wherein said pivot axis is located at an intersection of said first reference axis and second reference axis.

17. A method of multiple axis sensing using a microelectromechanical systems (MEMS) sensor, said MEMS sensor including a movable element spaced apart from a surface of a substrate, said movable element including first sense elements, said MEMS sensor further including second sense elements attached to said substrate, said second sense elements being immovable relative to said surface of said substrate, wherein said second sense elements are oriented substantially parallel to one another and are arranged adjacent to said first sense elements, wherein said method comprises:
detecting first and second motion of said movable element relative to said second sense elements, said movable element being adapted to undergo said first motion in response to a first force, said movable element being further adapted to undergo said second motion in response to a second force, said first and second forces being mutually orthogonal, and said first and second forces being substantially parallel to said surface of said substrate;
determining a first magnitude of said first force in response to said first motion; and
determining a second magnitude of said second force in response to said second motion.

18. The method of claim 17 wherein said detecting comprises:
detecting said first motion as translational motion of said movable element in response to said first force, said translational motion being substantially parallel to said surface of said substrate; and
detecting said second motion as pivotal motion of said movable element about a pivot axis that is substantially perpendicular to said surface of said substrate in response to said second force.

19. The method of claim 17 wherein said first and second sense elements include a first group of adjacent pairs of said first and second sense elements, a second group of adjacent pairs of said first and second sense elements, a third group of adjacent pairs of said first and second sense elements, and a fourth group of adjacent pairs of said first and second sense elements, and wherein said first and fourth groups are positioned opposing one another on opposite sides of a first reference axis, said second and third groups are positioned opposing one another on opposite sides of said first reference axis, said first and second groups are positioned opposing one another on opposite sides of a second reference axis, said third and fourth groups are positioned opposing one another on opposite sides of said second reference axis, said first and second reference axes being substantially parallel to said surface of said substrate, and said second reference axis being orthogonal to said first reference axis, and:
said determining said first magnitude comprises computing a first summation of capacitances between said first and second sense elements of said second and third groups subtracted by a second summation of capacitances between said first and second sense elements of said first and fourth groups to determine said first magnitude of said first force; and
said determining said second magnitude comprises computing a third summation of capacitances between said first and second sense elements of said first and third groups subtracted by a fourth summation of capacitances between said first and second sense elements of said second and fourth groups to determine said second magnitude of said second force.

20. The method of claim 17 wherein said movable element further includes first and second ends, and a rotational axis located between said first and second ends to form a first section between said rotational axis and said first end and a second section between said rotation axis and said second end, said first section exhibiting a greater mass than said second section, said MEMS sensor further includes a third sense element opposing said first section of said movable element and a fourth sense element opposing said second section of said movable element, and said method further comprises:
detecting third motion of said movable element about said rotational axis relative to said third and fourth sense elements, said movable element being adapted to undergo said third motion about said rotational axis in response to a third force, said third force being substantially perpendicular to said surface of said substrate; and
determining a third magnitude of said third force in response to said third motion.
